(19) United States
(12) Patent Application Publication
(10) Pub. No.: US 2003/0150109 A1
(43) Pub. Date: Aug. 14, 2003

(54) Method of manufacturing a circuit board

(75) Inventor: Takashi Magoi, Shiga (JP)

Correspondence Address: SUGHRUE MION, PLLC, 2100 PENNSYLVANIA AVENUE, N.W., WASHINGTON, DC, 20037, US

(73) Assignee: NEC ELECTRONICS CORPORATION

(21) Appl. No.: 10/359,219

(22) Filed: Feb. 6, 2003

(30) Foreign Application Priority Data
Feb. 14, 2002 (JP) 36529/2002

(51) Int. Cl. H05K 3/36; H05K 3/02

(52) U.S. Cl. 29/846; 29/830

(57) ABSTRACT

A circuit board is manufactured such that a laminated conductive pattern is formed directly on a surface of an insulating board made of a resin board by plating. The circuit board is subjected to heat treatment at temperatures higher than the softening point at which the resin board is softened and lower than a thermal point at which the conductive pattern is not displaced on the board. The circuit board manufactured in such a manner is able to have the insulating board and the conductive pattern strongly bonded to one another and to prevent displacement of laminated conductive pattern due to flow of resin.

### BACKGROUND OF THE INVENTION

1. Field of the Invention

The present invention relates to a method of manufacturing a circuit board, and more particularly to a method of manufacturing a circuit board incorporating resin-encapsulated electronic components thereon.

2. Description of the Prior Art

Some of resin-encapsulated electronic components are fabricated by mounting an electronic device such as an LSI chip on a lead frame or a circuit board and then encapsulating the same with resin. When employing a lead frame to form a resin-encapsulated electronic component, a chip is mounted on a die pad of the lead frame and then the electrodes of a chip are electrically connected to leads through bonding wires or the like, respectively. Thereafter, a main portion of the lead frame, together with the chip, is encapsulated with resin and then an unnecessary portion of the lead frame exposed from the resin is cut and removed.

On the other hand, when employing a circuit board, configured to have a large number of sets of conductive patterns including a die pad and leads of a lead frame formed on one sheet of insulating substrate, to form a resin-encapsulated electronic component, the component is manufactured as follows: a large number of chips are mounted on conductive patterns corresponding to die pads of the circuit board; and electrodes of each chip and the corresponding conductive patterns on the circuit board are electrically connected to each other through bonding wires, etc.; and then, the chips and the circuit board are encapsulated with resin; and finally, the circuit board (mother board) encapsulated with resin is cut down and separated into sub-circuit boards, i. e., electronic components.

In an electronic component of this type, since an insulating board has fine conductive patterns supportively formed thereon, the conductive patterns can be formed near one another. In addition, since joints through which a die pad and leads are electrically connected to each other can be made small, the so-called batch-production manufacture becomes possible in which a large number of electronic components are simultaneously manufactured from one sheet of large circuit board (mother board). Also, since a face used to bond the resin and the insulating board together is wide, an electronic component is excellent in moisture resistance though it is small. Furthermore, since the cutting width can be reduced to about several tens of microns when cutting the resin-encapsulated motherboard by using a rotating blade, the amount of a resin to be removed can be reduced to save the associated resource. Consequently, an electronic component using a circuit board has higher integration than that observed when using a lead frame and hence the electronic component fabricated through a circuit board is suitable for a small electronic component.

In a circuit board for use in this application, in general, conductive patterns are formed by bonding a conductive foil on an insulating board through adhesive agent. If the circuit board is heated to mount a chip thereon, then adhesive agent is softened, making the conductive patterns displaced. The displacement of the conductive patterns does not become serious when chip size is large. However, when forming the electronic component incorporating a chip, the one side of which is about 0.3 mm, on a circuit board, the width of the conductive pattern becomes so fine, i. e., about 0.02 mm and accordingly, when the conductive pattern is heated to a high temperature, it is displaced and is peeled off at worst. Thus, the circuit board in which a conductive foil is bonded to an insulating board through an adhesive agent is unsuitable for a small electronic component.

For this reason, as shown in FIG. 1, there has been used a circuit board in which conductive patterns 2 and 3 are directly formed on an insulating board 1 without the aid of an adhesive agent. The insulating board 1 is made of heat resistive resin such as a polyimide resin. Then, the conductive patterns 2 and 3, which are formed on both sides of the insulating board 1, are configured to have a large number of sets of the conductive patterns, each set consisting of large diameter areas 22, 23 and small diameter areas 42, 43. In this manner, the insulating board 1 and the conductive patterns 2, 3 constitute the circuit board 4, in which the corresponding areas on front and backsides of the board are electrically connected to each other via a connecting component (not shown). A semiconductor pellet 5 as a chip is mounted on the large diameter area 22 of the conductive pattern 2. Each of electrodes (not shown) on the pellet 5 and the small diameter area 42 of the conductive pattern 2 are electrically connected to each other through a bonding wire 6. The circuit board 4 is covered with-a resin 7 for protecting the pellet 5 and the wires 6. The circuit board 4 covered with a resin 7 is cut down along broken lines in the figure by a cutting tool such as a rotating blade and then divided into individual electronic components in a batch-production manner.

The above-mentioned circuit board 4 is manufactured as follows.

First, both surfaces of the insulating board 1 are roughened as shown in FIG. 2A and plating catalyst (not shown) is applied to roughened surfaces 21 and 41.

The insulating board is dipped into electroless copper plating liquid to form electroless copper plating layers 28 and 48 on the roughened surfaces 21 and 41, respectively, as shown in FIG. 2B.

As shown in FIG. 2C, the electroless copper plating layers 28 and 48 are covered with photosensitive resist films 9 and 10, respectively, which are in turn etched into a predetermined pattern to form windows.

Electrolytic copper plating layers 11 and 12 are respectively laminated on the electroless copper plating layers 28 and 48 which are exposed through the windows 29 and 49, 30 and 50 as shown in FIG. 2D. Subsequently, the resist films 9 and 10 are removed, and then the electroless copper plating layers 28 and 48 under the resist films 9 and 10 are removed to form the circuit board 4 including the conductive patterns 2 and 3, which have predetermined patterns, as shown in FIG. 1.

Since the circuit board 4 has the conductive patterns made of copper and including the electroless plating layer directly formed on the insulating board 1, i. e., without through an adhesive agent layer, the conductive pattern can be made fine and is rarely peeled off from the insulating board 1 even when the circuit board 4 is heated, whereby the circuit board 4 becomes suitable for use in the manufacture of a small electronic component.

It should be noted that an electronic component to be mounted on the surface of an external printed circuit board has to withstand the heating during the reflow of solder. For this reason, the insulating board 1 and the resin 7 are realized by employing a heat resistive material. In addition, an electronic component needs to be small in size and further, to be thin in order to provide compactness and therefore, the circuit board 4 and the resin 7 also need to be thin. In general, the adhesive agent used to bond the chip 5 onto the conductive pattern 22 is realized by employing solder, a conductive resin, etc. In this case, the thickness of the adhesive agent directly affects the thickness of an electronic component. Moreover, when the thickness of the adhesive agent applied to the conductive pattern 22 varies and a chip is mounted on the agent, the adhesive agent protrudes from the conductive pattern 22 in some cases. When the adhesive agent protrudes from the conductive pattern 22, the adhesive agent is probably exposed to the outside from the outer wall of the resin 7. If the adhesive agent is exposed from the outer wall of the resin 7, the adhesive agent probably is located next to or comes to contact the external charging portion so that reduction in withstand voltage or short-circuiting between the electronic component and the external charging portion results. To avoid such unfavorable phenomenon, chip mounting is not done through usage of an adhesive agent such as solder, but done through a method for directly connecting the chip 5 to the conductive pattern 22 by means of a thermal compression bonding method or an ultrasonic bonding method.

The above-mentioned thermal compression bonding method or ultrasonic bonding method allows mounting of the chip 5 only though local heating of the chip and therefore, does not subject the entire circuit board 4 to exposure in the ambient at a high temperature for a long period of time. However, the circuit board 4 also needs to be heated to about 300 degrees to provide sufficient strength of adherence between the board and the chip.

On the other hand, when using the circuit board that is configured to have larger than one hundred sets of conductive patterns formed on one sheet of mother board 1 to manufacture an electronic component, it takes time to mount chips on all the conductive patterns and as a result, the circuit board 4 comes to be exposed to the ambient at a high temperature for a long period of time. For this reason, even when the chip 5 is mounted using the thermal compression bonding method or the ultrasonic bonding method, the insulating board 1 needs to have heat resistivity.

A resin thermally resistive to thermal compression is typified such as by a liquid crystal polymer resin. However, this resin is poor in adhesion with an electroless plating layer and is not preferable as the circuit board 4 because conductive pattern's resistance against peeling of conductive pattern from a liquid crystal polymer resin is low, i. e., 0.6 Kg/cm.

The following technique is disclosed in JP 10-168577 A (prior art). First, an insulating board made of a liquid crystal polymer resin is etched and catalyst is applied thereto, and the resultant board is electrolessly plated with copper, and then, the resultant board is electrolytically plated with copper, and further, is electrolessly plated with nickel. When the insulating board is subjected to the thermal treatment in ambient at the temperature of about 50 to about 250 degrees to cure nickel, the adherence between the electrolytic plated copper and the electrolessly plated nickel is enhanced owing to the anchor effect, which is observed between the above-stated two metals. Thereafter, the electrolytic copper plating, the electrolytic nickel plating and the electrolytic gold plating are carried out, and then the resultant board is subjected to the thermal treatment in ambient at the temperature of 130 to 175 degrees to remove moisture from the insulating board. The circuit board formed in such a manner shows no thermal expansion during thermal treatment in ambient at a temperature of 250 degrees for 10 minutes at all.

However, when a chip is mounted by the thermal compression bonding method through compression on a plating layer while being heated at a temperature of about 300 degrees, the insulating board forms deformation indications due to the heating and compression, probably displacing the insulating board and the plating layers from one another. To prevent such unfavorable phenomenon, adherence between the insulating board and the plating layers needs to further be enhanced.

### SUMMARY OF THE INVENTION

The present invention has been proposed in order to solve the above-mentioned problems associated with the prior art. Thus, an object of the present invention is to provide a method of manufacturing a circuit board in which an insulating board having conductive patterns formed thereon is heated at temperature higher than its softening point to make a material of the insulating board penetrate into pores, having a specific depth, of the conductive patterns for enhancement of adherence between the insulating board and the conductive patterns. The detailed configuration of the present invention is as follows.

A method of manufacturing a circuit board according to the present invention, includes: forming an electroless plating layer on a roughened surface of a film-like resin board; covering the electroless plating layer with a photosensitive resist film and forming a predetermined pattern containing openings in the resist film; forming an electrolytic plating layer on the electroless plating layer exposed through the openings of the resist film; removing the resist film; removing the electroless plating layer under the resist film to form a laminated conductive pattern having the electroless plating layer and the electrolytic plating layer on the resin board; and heating the resin board having the conductive pattern formed thereon at temperature range of higher than a softening point, the softening point being defined such that the resin board is softened, and lower than a specific thermal point, the specific thermal point being defined such that the conductive pattern is not displaced on the resin board.

### BRIEF DESCRIPTION OF THE DRAWINGS

FIG. 1 is a transverse cross sectional view of a main portion showing a middle structure in manufacture of an electronic component using a conventional circuit board;

FIG. 2A is a transverse cross sectional view of a main portion useful in explaining a method of manufacturing a circuit board shown in FIG. 1;

FIG. 2B is a transverse cross sectional view of a main portion useful in explaining a manufacturing process next to FIG. 2A;

FIG. 2C is a transverse cross sectional view of a main portion useful in explaining a manufacturing process next to FIG. 2B;

FIG. 2D is a transverse cross sectional view of a main portion useful in explaining a manufacturing process next to FIG. 2C;

FIG. 2E is a transverse cross sectional view of a main portion useful in explaining a manufacturing process next to FIG. 2D;

FIG. 3 is a transverse cross sectional view useful in explaining a manufacturing process, according to the present invention, next to FIG. 2D and showing a structure of an enlarged main portion of a circuit board formed through this manufacturing process; and

FIG. 4 is a graphical representation useful in explaining a heating process to enhance adherence between a substrate and a conductive pad.

### DETAILED DESCRIPTION OF THE PREFERRED EMBODIMENTS

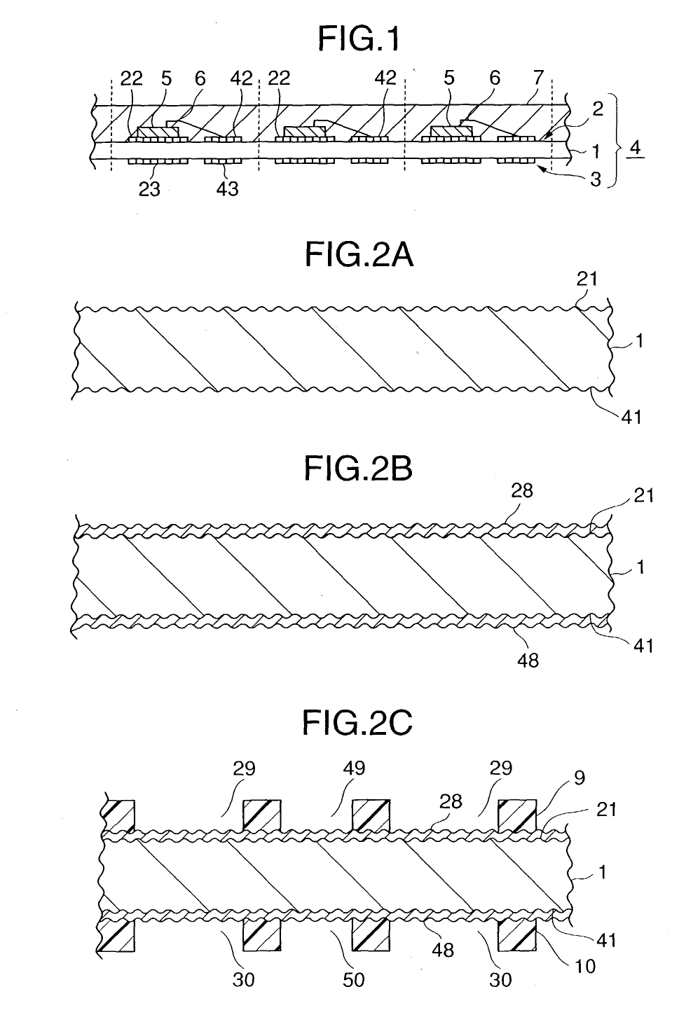

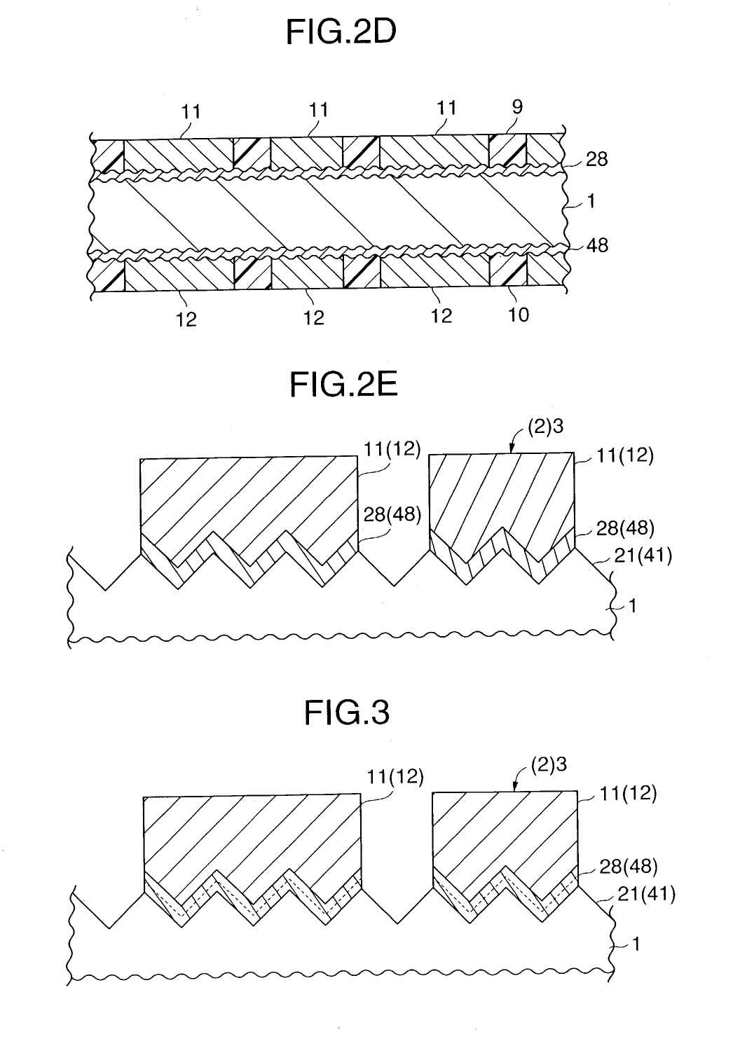

Preferred embodiment of the present invention will be described below in detail with reference to FIG. 3. In the figure, the same constituent elements as those of FIG. 1 and FIGS. 2A to 2E are denoted by the same reference numerals, and the repeated description is omitted for simplicity. A method of manufacturing a circuit board according to the present invention includes the process steps shown in FIGS. 2A to 2D and explained in the description of the conventional technique, which process steps just complete formation of conductive patterns.

An insulating board 1 made of a resin and having heat resistivity is first prepared. This insulating substrate 1 may be a liquid crystal polymer resin having heat resistivity and abrasion resistivity, and both surfaces thereof are roughened to increase an area for use to bond a layer on the surface and the surface. Thus, even when employing an insulating board made of a material on which an electroless-plating layer is hardly formed when directly being plated, the adherence between the insulating substrate and an electroless-plating layer will be enhanced.

As shown in FIG. 2A, both surfaces of the insulating substrate 1 are roughened. The operation for roughening is done using a sand blasting method of spraying a surface with polygonal fine particles of alumina or silica to mechanically roughen a surface. In this case, either a dry blasting method of spraying a board with fine particles through usage of air pressure or a wet blasting method of spraying a board with liquid containing fine particles dispersed therein may be employed. Alternatively, a method of dipping a board into acid or alkali liquid and etching the same for formation of roughened surface may optionally be employed. Degree to which a surface is to be roughened varies depending on a width and/or thickness of conductive pattern to be formed and typically, a surface is roughened with roughness of 0.1 to 10 μm. The term “roughness” described herein means an arithmetic mean roughness that is defined such that a surface of a certain length is partially extracted from an entire surface and a mean line of irregularity over the length is determined, and an integration of areas of irregularity protruding from the mean line is performed in the distance domain, and then, the value of integration is divided by the length.

As shown in FIG. 2B, for example, the plating catalyst such as palladium-tin colloid is applied to the roughened surfaces of the insulating board 1 and then the insulating board 1 is dipped into the electroless copper plating liquid. As a result, the plating metal, which preferably consists of copper, is deposited on the roughened surfaces of the insulating board 1 to form the electroless plating layers 28 and 48 on the roughened surfaces, respectively. The thickness of the electroless plating layers 28 and 48 is made to be 0.2 to 5 μm.

As shown in FIG. 2C, the insulating board 1 having the electroless plating layers 28, 48 formed on both surfaces thereof is covered with the photosensitive resist films 9 and the photosensitive resist films 9, 10 are exposed through a mask having a predetermined pattern, and then are developed to form the openings 29, 49, 30 and 50 in the resist films. The electroless plating layers 28, 48 exposed to the outside through the openings 29, 49, 30 and 50 are used as an electrode (cathode) for subsequent electrolytic plating.

As shown in FIG. 2D, when electrolytic copper plating is carried out using the electroless plating layers 28, 48 as a cathode, which layers are exposed to the outside through the openings 29, 49, 30 and 50, the electrolytic plating layers 11, 12 are laminated on the electroless plating layers 28, 48 exposed to the outside through the openings 29, 49, 30 and 50, respectively. The thickness of the electrolytic plating layers 11, 12 is determined such that the thickness of the conductive pattern having the electroless plating layer and the electrolytic plating layer laminated thereon falls within the range of 5 to 50 μm.

The electrolytic plating layers 11, 12 are thus formed and the resist films 9, 10 are removed, thereby providing the insulating board 1 having the electrolytic plating layers 11, 12 laminated on the main portions of the electroless plating layers 28, 48, respectively. In addition, when the electroless plating layers 28, 48 are etched and removed through the electrolytic plating layers 11, 12 as an etching mask, thereby providing the insulating board 1 having the conductive patterns 2, 3 formed thereon, as shown in FIG. 1.

The inner surface of the electroless plating layer 28 (48) of the conductive pattern 2 (3) of this circuit board is formed along the irregularity of the roughened surface 21 (41) of the insulating board 21 as shown in FIG. 2E. In addition, the irregularity of the outer surface of the electroless plating layer 28 (48) is determined depending on the surface roughness (0.1 to 10 μm) and the thickness (0.2 to 5 μm) of the electroless plating layer 28 (48). Then, the electrolytic plating layer 11 (12) is formed on the outer surface of the electroless-plating layer.

It should be noted that connection between the inner surface of the electroless plating layer 28 (48) and the roughened surface 21 (41) is due to engagement between the respective irregularities. Thus, the adherence between the inner surface of the electroless plating layer 28 (48) and the roughened surface 21 (41) is determined in proportion to the area over which the corresponding surfaces contact one another. For this reason, as the width of the electroless plating layer is narrowed, the associated adherence is correspondingly reduced and the adherence between the laminated conductive pattern 2 (3) including the electrolytic plating layer 11 (12) and the substrate is also correspondingly weakened. According to the present invention, in order to suppress decrease in adherence therebetween, the circuit board 13 is subjected to heat treatment in the next process. When the heating temperature is made higher than the softening point of heat resistive resin, the surface of the heat resistive resin begins flowing. When the heating temperature is made further higher, in general, the resin is not molten but is carbonized so that the heat resistive resin loses resin property. Also, when the resin is heated for a long period of time while maintaining the temperature higher than the softening point of resin, minute flow occurs in the surface of the resin.

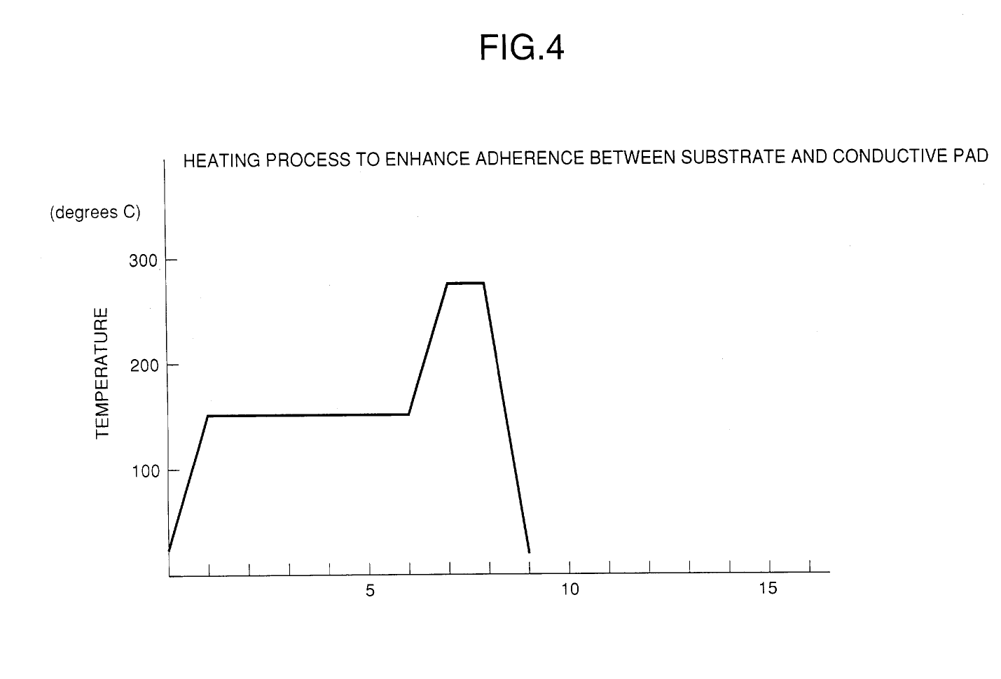

The heated conductive pattern 2 (3) is displaced from its normal place as the resin begins flowing because a support for the conductive pattern becomes unstable, which phenomenon is due to difference in the magnitude dependence of thermal expansion of the conductive pattern on the direction in which the conductive pattern is formed. In addition, when the insulating board 1 is rapidly heated, moisture in the resin is evaporated to increase its vapor pressure within the resin so that the resin shows cubical expansion. The increase in pressure under the conductive pattern expands the volume under the conductive pattern so that the conductive pattern is peeled off from the insulating board 1. Thus, the heat treatment in the present invention should be performed increasing the temperature slowly to remove the moisture from the board. More specifically, rise in the temperature from a room temperature to near 150 degrees should be made over 30 minutes to 1 hours and removal of the moisture from the insulating board at the temperature near 150 degrees should be made over 4 to 5 hours. As a result, the cubical expansion of resin due to the moisture can be suppressed. Thereafter, the temperature is made to rise again from near 150 degrees to near the target temperature (280 degrees in this case) higher than the softening temperature, 250 degrees, of the insulating board (the liquid crystal polymer resin in this case) for 30 minutes to 1 hour (refer to FIG. 4).

The circuit board according to the present invention is shown in FIG. 3. This circuit board is processed such that the circuit board shown in FIG. 2E is heated to temperatures higher than the softening point at which the resin board 1 is softened and lower than displacement thermal point at which the conductive pattern begins being displaced by softening of resin of the board 1. The thermal plastic resin, having a softening temperature of, for example, 250 degrees such as the liquid crystal polymer resin can be processed at the temperature of 255 to 300 degrees. When the board is placed at the upper limit of the above-described temperature range, the insulating board 1 probably deforms in a relatively short period of time so that the conductive pattern is displaced from its position and never returns back to its original position. For this reason, in the case of liquid crystal polymer resin whose softening temperature is 250 degrees, it is desirable to make temperature not exceed flow point (300 degrees) at which the resin flows in a short period of time (1 to 3 minutes) upon heat treatment of insulating board. Furthermore, in order to prevent the conductive pattern from being displaced from its position even when the heating time becomes about 5 minutes longer than a desired heating time, it is preferable to define as an optimal thermal point a temperature lower by about 20 degrees than the above-mentioned displacement thermal point, i. e., 280 degrees. When the circuit board is heated while maintaining optimal thermal point for 10 to 60 minutes, the liquid crystal polymer resin of the insulating board is microscopically diffused into pores of the porous electroless plating layer and is bonded to surfaces of the pores at the interface between the roughened surfaces 21, 41 of the insulating board 1 and the electroless plating layers 28, 48. This is denoted by a broken line in the figure. As a result, the adherence between the insulating board 1 and the electroless-plating layer 28 is remarkably enhanced. In addition, the mutual diffusion is also caused between the electroless plating layers 28, 48 and the electrolytic plating layers 11, 12 to enhance the adherence therebetween.

Heating the insulating board having the electroless plating layer sandwiched between the insulating board and the electrolytic plating layer to the temperature higher than its softening point makes the resin of the insulating board diffused into the electroless plating layer through the bonding interface therebetween. Furthermore, upper portion of the resin is softened and at the same time, the resin and the conductive pattern thermally expand, so that the friction therebetween due to the difference in their thermal expansion coefficient occurs at the bonding interface. In addition, when the temperature of the resin surface decreases after completion of the heating, the conductive pattern including the electroless plating layer and located on the insulating board is thermally compressed prior to compression of the resin in the softening state because of its higher heat conductivity than that of resin, thereby allowing the resin filled within the pores of the electroless plating layer to mate with the pores. As a result, the adherence between the resin and the plating layers is enhanced.

In this manner, when the circuit board to which the conductive pattern including the electroless plating layer is bonded is heated to soften the resin thereof, the adherence between the conductive pattern and the resin is enhanced. For this reason, even when employing a liquid crystal polymer resin, whose ability to be bonded to a plating layer is low, as the material of the insulating board, the adherence equal to or larger than 1.0 Kg/cm can be achieved between the resin and the insulating board, enabling to provide a practical circuit board.

Consequently, the heat treatment according to the present invention is preferably performed using temperatures higher, by not lower than 5 degrees, than the softening point of the insulating board and not higher than a thermal point at which the resin does not flow in about 5 minutes. For example, in the case of the liquid crystal polymer resin being employed, the heat treatment is performed at temperatures of 255 to 290 degrees and more preferably at temperatures of 260 to 285 degrees.

The insulating boards 1 may be realized by employing a heat resistive polyimide resin (brand name is “Kapton” manufactured by Dupont Kabushiki Kaisha; brand name is “Upilex” manufactured by Ube Industries, Ltd.) or a liquid crystal polymer resin (brand name is “Vecstar” manufactured by Kuraray Co. Ltd.; brand name is “BIAC” manufactured by Japan Gore-Tex Inc.).

As described so far, degree to which the conductive pattern is bonded to the insulating board can be enhanced and therefore, even when the circuit board is heated and the conductive pattern is given a heavy load in the process steps such as the mounting process or the wire bonding process, it is possible to prevent peeling of the conductive pattern from the board and to thereby manufacture a highly reliable electronic component.

As set forth hereinabove, according to the present invention, a circuit board in which a conductive pattern including an electroless plating layer is formed on the insulating board through the plating process is heated to temperatures higher than its softening point, thereby improving mechanical connection adherence between the insulating board and the conductive pattern, and further allowing manufacture of highly reliable electronic component.

In addition, a circuit board according to the present invention includes a resin board made of either a heat resistive polyimide resin or a heat resistive liquid crystal polymer resin, and an electroless plating layer of 0.2 to 5 μm in thickness provided thereon, and further an electrolytic plating layer made of copper provided on the electroless plating layer to have a total thickness of 5 to 50 μm. In this case, the roughness of individual interfaces between the corresponding layers, i, e., the resin board, the electroless plating layer and the electrolytic plating layer is made to be 0.1 to 10 μm.

Furthermore, a method of manufacturing a circuit board according to the present invention including: an directly forming an electroless plating layer as a base layer on an insulating board; and forming an electrolytic plating layer thereon as a conductive pattern. A resin board having the above-mentioned conductive pattern formed thereon is subjected to heat treatment at temperatures higher than the softening point at which the resin board is softened and lower than a thermal flow point at which the resin is made to flow. The circuit board manufactured in such a manner becomes the circuit board having preferable adherence property because the circuit board employs a liquid crystal polymer resin having high thermal resistivity as a resin board.

While the present invention has been particularly shown and described with reference to the preferred embodiment, it will be understood that the various changes and modifications will occur to those skilled in the art without departing from the scope and true spirit of the invention. The scope of the invention is, therefore, to be determined solely by the appended claims.

What is claimed is:

1. A method of manufacturing a circuit board, comprising the steps of:
forming an electroless plating layer on a roughened surface of a film-like resin board;
covering said electroless plating layer with a photosensitive resist film and forming a predetermined pattern containing openings in said resist film;
forming an electrolytic plating layer on said electroless plating layer exposed through said openings of said resist film;
removing said resist film;
removing said electroless plating layer under said resist film to form a laminated conductive pattern having said electroless plating layer and said electrolytic plating layer on said resin board; and
heating said resin board having said conductive pattern formed thereon at temperature range of higher than a softening point of said resin board and lower than a specific thermal point, said specific thermal point being defined such that said conductive pattern is not displaced on said resin board.

2. The method of manufacturing a circuit board according to claim 1, wherein said resin board is made of a liquid crystal polymer resin.

3. The method of manufacturing a circuit board according to claim 2, wherein in the step of heating said resin board, said resin board is heated at temperatures of 255 to 290 degrees for 10 to 60 minutes.

4. The method of manufacturing a circuit board according to claim 1, wherein said laminated conductive pattern is made of copper.

5. The method of manufacturing a circuit board according to claim 1, wherein arithmetic mean roughness at a contact surface between said resin board and said laminated conductive pattern is 0.1 to 10 μm, and a thickness of said electroless plating layer is 0.2 to 5 μm, and a thickness of said laminated conductive pattern is 5 to 50 μm.
